(19) United States
(12) Patent Application Publication
(10) Pub. No.: US 2026/0215297 A1
(43) Pub. Date: Jul. 23, 2026

(54) Package with Lateral Semiconductor Flip-Chip and Bond Wires Crossing and Bridging a Routing Structure

(71) Applicant: Infineon Technologies Austria AG, Villach (AT)

(72) Inventor: Chee Yang Ng, Muar (MY)

(21) Appl. No.: 19/450,192

(22) Filed: Jan. 15, 2026

(30) Foreign Application Priority Data
Jan. 23, 2025 (DE) 102025102421.9

(51) Int. Cl. H10W 70/60; H10W 70/05; H10W 72/50; H10W 90/10

(52) U.S. Cl. CPC H10W 70/611; H10W 70/093; H10W 72/547; H10W 90/10

(57) ABSTRACT

A package includes a carrier having a main surface on and/or in which an electrically conductive routing structure is formed, a first electronic component being a lateral semiconductor chip and being mounted in a flip-chip configuration on the carrier to be electrically coupled with the routing structure, and a plurality of electrically conductive bond wires electrically connecting the carrier and/or the first electronic component. The bond wires, in a plan view on the carrier, cross the routing structure in at least one crossing region and extend above or below the routing structure for bridging the routing structure in the at least one crossing region.

### TECHNICAL FIELD

The present invention relates to a package and to a method of manufacturing a package.

### BACKGROUND

A package, for instance for automotive applications, provides a physical containment for one or more electronic chips comprising one or more integrated circuit elements. Examples of integrated circuit elements of packages are a metal oxide semiconductor field effect transistor (MOSFET), an insulated-gate bipolar transistor (IGBT), and a diode.

There is still potentially room to enable package manufacture with short electric paths and low loss. More specifically, a lower direct current resistance and a lower parasitic resistance may be desired in the context of short interconnects.

### SUMMARY

There may be a need for a package with short electric paths and low loss.

According to an exemplary embodiment, a package is provided which comprises a carrier having a main surface on and/or in which an electrically conductive routing structure is formed, a first electronic component being a lateral semiconductor chip and being mounted in a flip-chip configuration on the carrier to be electrically coupled with the routing structure (for example so that one or more chip pads of the first electronic component are electrically coupled with one or more traces of the routing structure), and electrically conductive bond wires electrically connecting the carrier (for example one or more traces of the routing structure of the carrier) and/or the first electronic component (for example one or more chip pads of the first electronic component), wherein the bond wires, in a plan view on the carrier, cross the routing structure in at least one crossing region and extend (in particular in a side view of the carrier) above or below the routing structure for bridging the routing structure in the at least one crossing region (for example without direct physical contact between bond wires and routing structure in the crossing region).

According to another exemplary embodiment, a method of manufacturing a package is provided, wherein the method comprises providing a carrier having a main surface on and/or in which an electrically conductive routing structure is formed, mounting a first electronic component being a lateral semiconductor chip in a flip-chip configuration on the carrier to be electrically coupled with the routing structure, electrically connecting the carrier and/or the first electronic component by electrically conductive bond wires, and arranging the bond wires, in a plan view on the carrier, to cross the routing structure in at least one crossing region and to extend above or below the routing structure for bridging the routing structure in the at least one crossing region.

According to an exemplary embodiment, a package may have a carrier (for instance an organic carrier such as a printed circuit board) with an electrically conductive routing structure (such as a horizontal wiring pattern with electric traces) in a surface region of the carrier. An electronic component which may be configured as a lateral semiconductor chip arranged in flip-chip configuration on the carrier may be electrically connected with the routing structure. Moreover, electrically conductive bond wires may establish an electrically conductive coupling of the carrier, the electronic component, or both. In vertical viewing direction onto the chip mounting surface of the carrier, the bond wires may cross or intersect the routing structure, while the bond wires may be arranged in a flyover configuration bridging the routing structure by extending above or below said routing structure. As a result, a package configuration with very short electrically conductive paths may be obtained thanks to the mounting of the lateral flip-chip on the preferably planar wiring structure of the carrier. Flyover-type bond wires may also contribute to short electrically conductive paths, since they may bridge the wiring structure rather than circumventing or bypassing them in a planar fashion. Advantageously, such short paths may lead to low losses and high signal integrity. Furthermore, low ohmic losses due to short paths may be beneficial in terms of thermal management, because only moderate heat dissipation may occur. Consequently, a package with high electrical and thermal reliability and performance may be obtained. At the same time, the package may be manufactured compact and therefore with reasonable effort. Advantageously, a package with short electric paths and low loss may be obtained.

Exemplary embodiments may also provide additional possibilities with a routable carrier and/or a flip chip configuration. In particular, this may enable at least one of top side cooling, omission of exposed tie-bars at a package external, an improved flexibility for different integration concepts with given chips, and/or an enhanced flexibility to match a footprint (i.e. a reference footprint, different creepage distance, etc.).

In the following, further exemplary embodiments of the package and the method will be explained.

In the context of the present application, the term “package” may particularly denote a device which may comprise for example one, two or more chips. For example, at least part of the latter may be mounted on a (in particular partially or entirely electrically conductive) carrier. Said constituents of the package may be optionally encapsulated at least partially by an encapsulant. Furthermore, an electric connection structure may form part of the package.

In the context of the present application, the term “carrier” may particularly denote a support structure (which may be at least partially electrically conductive) which serves as a mechanical support for the electronic chip(s) to be mounted thereon, and which may also contribute to the electric interconnection between the electronic chip(s) and the periphery of the package. In other words, the carrier may fulfil a mechanical support function and an electric connection function. A carrier may comprise or consist of a single part, multiple parts joined via encapsulation or other package components, or a subassembly of carriers. Preferably, the carrier may be an organic laminate carrier such as a printed circuit board. It is also possible that the carrier forms part of a leadframe. In such an embodiment, the carrier may be or may comprise a die pad. When the carrier is a leadframe, a redistribution layer (RDL) and multiple traces may be provided as well. For example, a pre-molded leadframe may be implemented, with just top side routing (as a first layer). Then, one or more flyover bond wires may be used for additional routing. This may lead to a two-layer-like routing capability of the package. It is also possible that the mentioned carrier is a DAB (Direct Aluminum Bonding) substrate, a DCB (Direct Copper Bonding) substrate, etc. Moreover, the carrier may also be configured as Active Metal Brazing (AMB) substrate.

In the context of the present application, the term “routing structure” may particularly denote an electrically conductive wiring arranged partially or entirely in a main surface of the carrier. For example, the routing structure may lie partially or entirely within a plane. Said plane may correspond to the main surface of the carrier. In particular, the routing structure may be a horizontal structure. It may also be possible that said routing structure provides an electric connection into an interior of the carrier, for instance by one or more vertical through connections such as metallic vias. The routing structure may comprise a patterned metal layer defining traces along which electric signals or current may flow during operation of the package.

In the context of the present application, the term “chip” may in particular denote an electronic component comprising a substrate in which at least one integrated circuit element is formed. For instance, the chip maybe a semiconductor chip (in particular a power semiconductor chip). The chip may be an active electronic device. In particular, the chip may be a semiconductor chip having at least one integrated circuit element (such as a monolithically integrated transistor) in a surface portion thereof. Said surface portion may be denoted as active region of the chip. The chip may be a bare die or may be already packaged or encapsulated. Semiconductor chips implemented according to exemplary embodiments may be formed for example in silicon technology, gallium nitride technology, silicon carbide technology, etc.

In the context of the present application, the term “lateral chip” may particularly denote a chip being configured as a lateral device. This may be in contrast to a vertical device. Such a lateral chip may be configured so that, during operation, charge carries flow along (or flow predominantly along) a lateral or horizontal direction (in particular rather than along a vertical direction). In contrast to vertical chips, the dominant current flow of lateral chips may be in a direction within a horizontal plane, in particular in parallel to a semiconductor substrate surface. For instance, all chip terminals of a lateral chip may be on the same main surface of the chip.

In the context of the present application, the term “flip-chip configuration” may particularly denote a configuration of a chip in which the chip is mounted on a carrier with its active region facing the carrier. The active region of the chip may be a surface region in which at least one integrated circuit element is integrated, in particular monolithically integrated. In a flip-chip attachment or arrangement, the chip or die may be attached to the carrier using a flip-chip method. The front side of the chip may face the carrier in a flip-chip configuration, whereas the back side of the chip may oppose the carrier.

In the context of the present application, the term “bond wire” may particularly denote an electrically conductive filament, wire or thread. In an assembled configuration, the bond wire may extend in a curved fashion, or straight. A bond wire may be made of a metallic material, such as aluminum, copper, silver and/or gold. For instance, a bond wire may have a diameter in a range from 5 μm to 700 μm, in particular in a range from 10 μm to 500 μm. For example, a bond wire may have a length of at least 500 μm or of at least 1 mm, in particular of at least 3 mm or of at least 10 mm. In particular, a bond wire may be configured for wire bonding, which may denote a method of making an interconnection between two electrically conductive structures. Such a bond wire may be connected with one section to a first connection partner and with another section to a second connection partner for electrically coupling the first and second connection partners. For example, a bond wire may have a round (in particular circular) or polygonal (in particular rectangular) cross-section, or may be embodied as a bond ribbon.

In the context of the present application, the term “crossing region” may particularly denote a virtual or imagined region around a crossing or intersection between a routing structure and a bond wire in a plan view. In particular, the crossing region may be denoted as a spatial region in which the routing structure crosses or seems to cross a bond wire in a plan view on routing structure and bond wire. In a side view, the routing structure may however be spaced with respect to the bond wire in said crossing region, for instance since the bond wire extends in the fashion of a bridge over a trace of the routing structure. In fact, bond wires crossing a routing structure in a plan view may extend above or below the routing structure in a side view in a bridging fashion.

In the context of the present application, the term “main surface” of a body may particularly denote the largest body or surface or one of the largest body surfaces. For instance, a body (such as a chip or a carrier) may be plate-shaped or substantially plate-shaped and may then have two opposing main surfaces separated by body material in a thickness direction and connected with each other by a circumferential edge.

In an embodiment, a highest vertical level up to which the first (and/or any other) electronic component extends may be higher than a highest vertical level up to which the bridging bond wires extend (see for example FIG. 7). Advantageously, this may lead to a package with a top side cooling functionality. For example, a wire bond loop may be located lower than the (for example GaN) flip-chip die. This can happen as a die (such as a GaN die) may be thicker, whereas a logic die may be thinner (for example 200 μm). It is for instance possible that the flip chip defines the highest or tallest region of the package or a preform thereof. Then, a flying bond wire may be located lower. In this case, it may be possible to enable top side cooling without disturbing bond wire.

In an embodiment, the bond wire may be located below the routing structure, in particular below a main surface of a laminate. For simplicity and low effort, it may also be possible to provide a double sided structure, with wire bonding at the other side of the carrier, etc.

In an embodiment, at least part of the bond wires are connected directly to the routing structure, in particular to an end section and/or to a middle section of the routing structure. Such a preferred embodiment may be of utmost advantage, since a direct connection between a bent or curved filament-type bond wire and an oblong planar trace of the routing structure may significantly shorten the electrically conductive connection paths. For example, the bond wire and the trace of the routing structure may be connected with each other with direct physical contact and without a further intermediate physical structure, or a bond pad or another electrically conductive connection medium (such as a sinter paste or solder) may be provided in a region where the bond wire and the trace of the routing structure physically intersect each other so as to be mutually electrically coupled with each other by said bond pad or other electrically conductive connection medium. In one embodiment, the bond wire-trace connection may be made at an end section of the bond wire and/or an end section of the trace of the routing structure. In another embodiment, the bond wire-trace connection may be made at a middle section of the bond wire and/or a middle section of the trace of the routing structure.

In an embodiment, for one, some or all bond wires of the package, one section of the respective bond wire is directly connected with one section of the routing structure, and another section of the routing structure is connected to a pad of the first (or any other) electronic component. For instance, routing structure and chip pad may be at the same vertical level. In an embodiment, a trace or wiring element of the routing structure may bridge a spatial range between a bond wire and a chip pad. In particular, one end section of said trace or wiring element of the routing structure may be connected with a bond wire, whereas an opposing other end section of said trace or wiring element of the routing structure may be connected with the chip pad. This may create a highly efficient interconnection of a flip-chip type lateral electronic component via routing structure and bond wire. A result of this may be an excellent electrical and thermal performance of the package thanks to very small losses.

In particular, one end of the respective bond wire may directly connect with one end of one routing structure, and another end of the routing structure may connect to one pad of the lateral semiconductor die. This can shorten the electrical distance between the bond wire and the lateral semiconductor die. The benefit of a bond wire which directly bonds on the routing structure, instead of directly bonding on the bond pad of the die (which, when flip-chipped downward, may not be easily accessible for wire bonding) may be that it can actually provide flexibility of an electrical connection between bond pads of the flip-chip die and corresponding vias, pads and/or leads. At the same time, this can shorten the length of the routing structure.

In an embodiment, for one, some or all bond wires of the package, one section of the respective bond wire is directly connected with one section of the routing structure, and another section of the bond wire is connected to a vertical electrical interconnector, for example a via, of the carrier. Such a vertical electrical interconnector may extend vertically through the carrier for establishing an electric coupling in vertical direction between two opposing main surfaces of the carrier. For instance, a metallized via, a metal post or a metal pillar may be used as such a vertical electrically interconnector. A respective end of the bond wire may connect an electrical pad (for instance of the routing structure or of at least one of the at least one electronic component) or one end of a vertical electrical interconnector of the carrier. In particular, the bond wire may directly connect the routing structure and the via, which may further shorten the electrical paths.

In an embodiment, at least part of the bond wires electrically couple (for example a respective trace of) the routing structure with at least one carrier pad of the carrier. A carrier pad may be a planar, for instance circular, metallic structure or land of the carrier. A bond wire may bridge such a carrier pad with respect to an oblong trace or wiring element of the routing structure. In an embodiment, it may also be possible that at least part of the bond wires may electrically couple at least one component pad of the first electronic component with at least one carrier pad of the carrier.

In an embodiment, the first electronic component has a plurality of chip pads only part of which being connected to the routing structure. At least one other pad of the first electronic component may be electrically connected in another way, for instance by a bond wire or a clip. In an embodiment, not every pad of the die is connected to the routing structure. It may also be possible that some of the pads of the die directly connect to carrier pads of the carrier. Those carrier pads may actually be an exposed part of some vias, so that chip pads of the die may electrically and directly connect the carrier pads and vias and bottom terminals (such as a metal part which functions as leads of the final package) in a vertical way. It may be sufficient that only part of the chip pads of the die connect to the routing structures, not necessarily all. This may depend on the routing characteristics for a specific package or application. For example, some flip-chip pads may connect to package external pads, and some routings may connect with other components.

In an embodiment, the package comprises a second electronic component being a lateral semiconductor chip and being mounted in a flip-chip configuration on the carrier to be electrically coupled with the routing structure. Thus, a front side of the second electronic component with its active region may face the carrier. Any of the above described features concerning the electric connection of the first electronic component may also apply to the second electronic component. For instance, all electronic components of the package may be flip-chip dies and/or lateral dies. Such a configuration may lead to an ultra-compact package with a highly efficient low-loss high-quality wiring architecture.

In another embodiment, the package may however comprise at least one vertical chip and/or at least one chip mounted face-up, i.e. with its active region facing away from the carrier.

In an embodiment, the package comprises a third electronic component being a lateral semiconductor chip and being mounted in a flip-chip configuration on the carrier to be electrically coupled with the routing structure. Thus, a front side of the third electronic component with its active region may face the carrier. Any of the above described features concerning the electric connection of the first electronic component may also apply to the third electronic component.

In an embodiment, the routing structure directly connects the first electronic component, in particular a power chip, and the third electronic component, in particular a logic chip. Preferably, the second electronic component is a further power chip. The logic chip may control both power chips. Both power chips may be transistor chips.

In an embodiment, the first electronic component, the second electronic component and the third electronic component are interconnected to form a half bridge. In the context of the present application, the term “half bridge” may particularly denote a circuit composed of an upper transistor switch (“high-side”) and a lower transistor switch (“low-side”) which are both controlled by a logic or control chip (or by a plurality of such logic or control chips). In particular, the first electronic component and the second electronic component may be upper and lower transistor switches, whereas the third electronic component may be the control or logic chip. For instance, the transistors may be MOSFETs. The transistors may be connected in a cascode arrangement. The two transistor switches may be turned on and off complementary to each other (in particular with a non-overlapping dead-time) by applying corresponding voltage waveforms at control terminals (such as gate terminals). A desired result may be an idealized DC-DC conversion scenario, where a square-wave mid voltage level switches between a first electric potential (such as a DC (direct current) bus voltage) and a second electric potential (such as ground). However, other shapes of an output signal may be possible which do not have a square-wave characteristic. The two transistors may be interconnected with a mutual connection of their drain terminals and with a mutual connection of their gate terminals. The mentioned half bridge configuration may be used as such or alone or may be combined with one or more further half bridges (or other electric circuits) to realize a more complex electric function. For instance, two such half bridges may form a full bridge.

Concerning the third component or chip, which may for example be a logic IC, this third chip may also be flip-chip attached to the carrier. However, the third chip can be also a normal logic IC and does not need to be flip-chip attached. Then the connection may be for example from the logic IC via the bonding wire(s) to the trace(s) and then to the power die(s). In such a scenario, it may be possible to provide a reverse bonding to keep the loop low.

In an embodiment, the first electronic component is a power chip, the second electronic component is a power chip, and the third electronic component is a logic chip. For example, the package may comprise two power dies and two logic dies (both controlling these two power dies). However, it is also possible to have two power dies and only one logic die controlling both power dies. Thus, a second logic chip is optional. Generally, exemplary embodiments may enable a very flexible package concept for various configurations.

In an embodiment, the first electronic component, the second electronic component and/or the third electronic component is or are a transistor chip, a power chip, a logic chip, a driver chip and/or a gallium nitride chip. In the context of the present application, the term “transistor chip” may in particular denote a chip, such as a semiconductor chip, in which at least a transistor may be integrated, in particular monolithically integrated. Optionally, the chip may comprise at least one further integrated circuit element, such as a diode or a further transistor. In particular, a respective chip with integrated transistor may be a field-effect transistor chip having a source terminal (or pad), a drain terminal (or pad) and a gate terminal (or pad). Alternatively, a respective chip with integrated transistor may be a bipolar transistor chip having an emitter terminal (or pad), a collector terminal (or pad) and a base terminal (or pad). Specific examples of the transistor chips are a metal oxide semiconductor field effect transistor (MOSFET), and an insulated-gate bipolar transistor (IGBT). In the context of the present application, the term “power chip” may in particular denote a chip, such as a semiconductor chip, configured for a power application, for instance a power switching application. In an embodiment, the chip(s) with transistor is/are configured as power semiconductor chips. Thus, a corresponding chip (such as semiconductor chip) may be used for power applications for instance in the automotive field. Corresponding integrated circuit elements may be made for instance in silicon technology or based on wide-bandgap semiconductors (such as silicon carbide, gallium nitride or gallium nitride on silicon). A semiconductor power package may comprise one or more inverter circuits, one or more half bridges, one or more full-bridges, one or more drivers, one or more logic circuits, etc.

In an embodiment, the carrier has a further main surface opposing said main surface, wherein an electrically conductive layer structure is formed on and/or in the further main surface of the carrier. The electrically conductive layer structure may be electrically coupled with the routing structure on the other side of the carrier by one or more vertical interconnect structures extending through a thickness direction of the carrier. The electrically conductive layer structure of the package may be used for mounting the package on a mounting base (such as a printed circuit board), for instance by soldering, sintering or electrically conductive glue.

A solder mask may cover part of the electrically conductive layer structure. The electrically insulating solder mask may be a patterned layer on the patterned electrically conductive layer structure for selectively exposing or covering respective sections of the electrically conductive layer structure.

In particular, the solder mask may be formed to shape an exposed pad at the bottom side of the carrier. Thus, there may be solder mask at the bottom side. However, it may also be possible to use solder mask on the top main surface of the carrier to separate multiple traces. This may be formed by a deposition process in addition to the routable carrier.

In an embodiment, the package comprises electrically conductive vias extending vertically through the carrier and connecting the routing structure with the electrically conductive layer structure. Such vias may establish a front side to back side coupling through the carrier.

In an embodiment, the carrier is a two-layer carrier with the routing structure arranged on the main surface of the carrier and the electrically conductive layer structure exposed at the further main surface of the carrier. In particular, the term “two-layer carrier” may particularly denote that the carrier comprises exactly two horizontal structured metal layers, one on the front side and another one on the back side of the carrier. In addition, a two-layer carrier may comprise metallic vertical through connections and/or electrically insulating material between the two horizontal structured metal layers. The routing structure and the electrically conductive layer structure may form the only two horizontal electrically conductive layer structures of the carrier. One electrically conductive layer structure may be used for the routable carrier design. An extra layer may come from wire bonding, where crossing traces connect opposite traces.

In an embodiment, the carrier is an organic substrate, a laminate substrate, a molded interconnect substrate (MIS), a pre-molded frame, or a leadframe. For example, a flip-chip may be mounted on a leadframe, and then wire bonding may be used to connect pads to other pads. A pre-molded QFN frame is another option. For example, a printed circuit board may be used as organic carrier or laminate.

In an embodiment, the carrier comprises a laminate substrate having an at least partially electrically insulating laminate between the first main surface and the second main surface of the carrier. Sad laminate may comprise organic material. In the context of the present application, the term “laminate” may particularly denote a flat body (such as a sheet or plate) formed by multiple interconnected laminate layers, i.e. layers which can be or which are interconnected by lamination. In particular, a laminate may comprise a material that is suitable for sticking several laminate layers, for instance made of the same material, together. Hence, a laminate may be a plate-shaped or sheet-shaped body made of one or multiple laminable or laminated layers. Said laminate layers may be connected or configured to be connectable with other layers by lamination. Lamination may denote a connection of laminable layers using elevated temperature, optionally accompanied by an additional mechanical pressure applied to stacked laminate layers. In particular, such a laminate may be a pressed multilayer stack of one or more dielectric organic layers and/or one or more metallic foils. One or more dielectric laminate layers may be for example prepreg layers. Prepreg is a material which comprises a resin, optionally with glass particles therein. The laminate may also comprise one or more metal layers, which may be copper foils. More generally, the laminate may comprise at least one dielectric layer which is capable of curing, polymerizing and/or cross-linking during a lamination process, thereby contributing to an adhesion force between multiple layers of a multilayer laminate. For instance, a laminate may be a chip substrate or a printed circuit board (PCB).

In particular, a laminate material or material of the laminate may be an epoxy resin or another polymer (like polyimide) or another insulating material filled with filler particles, in particular glass particles, more particularly glass fibers. Such a material may be provided as prepreg, i.e. as a sheet in which the epoxy resin is not or not fully cured, so that it can become liquid by supplying thermal energy. In a laminate, such a prepreg sheet may be combined with one or more copper foils which can be attached upon lamination. Resin Coated Copper (RCC) is a combination of a copper foil and an uncured epoxy resin without glass fibers.

In another embodiment, the carrier comprises a molded interconnect substrate (MIS). A molded interconnect substrate may comprise one or more molding layers in which one or more electrically conductive trace layers and/or one or more electrically conductive through connections may be embedded.

In yet another embodiment, the carrier may also be a leadframe. In the context of the present application, the term “leadframe” may particularly denote a sheet-like metallix structure which can be bent, punched, and/or patterned so as to form leadframe bodies as mounting sections for mounting chips, and connection leads for electric connection of the package to an electronic environment. In an embodiment, the leadframe may be a metal plate (in particular made of copper) which may be patterned, for instance by stamping or etching. Forming a chip carrier as a leadframe is a mechanically as well as electrically highly advantageous configuration in which a low ohmic connection of chips can be combined with a robust support capability of the leadframe. Furthermore, a leadframe may contribute to the thermal conductivity of the package and may remove heat generated during operation of the chip(s) as a result of the high thermal conductivity of the metallic (in particular copper) material of the leadframe.

In an embodiment, the routing structure electrically couples the first electronic component with a second electronic component, and optionally also with a third electronic component. For example, said three electronic components may be configured as described above. A direct connection between one power die and one logic die may be established, because a controlling signal may be conducted from one logic die to a power die. This may provide maximum flexibility for integration. If a connection in the same plane is not possible or there is a need for an additional plane, then it may be possible to use a wire bond to fly over to connect to keep the carrier layer count low for low manufacturing effort.

In an embodiment, the package comprises an encapsulant, for example a mold compound, encapsulating at least part of the at least one chip, the bond wires and part of the carrier. Hence, a common encapsulation of package constituents may be accomplished. In the context of the present application, the term “encapsulant” may particularly denote a material, structure or member surrounding at least part of the chips (and optionally part of a carrier) to provide mechanical protection, and optionally electrical insulation and/or a contribution to heat removal during operation. In particular, said encapsulant may be predominantly or even entirely electrically insulating, for instance a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel). In still another embodiment, the encapsulant may be a laminate of stacked layers (for instance comprising prepreg and/or resin sheets).

As substrate or wafer forming the basis of the chip(s), a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages of the present invention will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 shows a plan view of all layers from a top side of a package according to an exemplary embodiment.

FIG. 2 shows a plan view of a first layer of the package according to FIG. 1.

FIG. 3 shows a plan view of a second layer of the package according to FIG. 1.

FIG. 4 shows a plan view of a bottom layer of the package according to FIG. 1.

FIG. 5 shows a plan view of a package according to another exemplary embodiment.

FIG. 6 shows a plan view of a package according to another exemplary embodiment.

FIG. 7 shows a cross-sectional view of a package according to another exemplary embodiment.

### DETAILED DESCRIPTION

The illustration in the drawing is schematically.

Before describing further exemplary embodiments in further detail, some basic considerations will be summarized based on which exemplary embodiments have been developed.

Gallium nitride (GaN) chips are interesting candidates for integration to harvest good performance of gallium nitride high speed capability. However, to enable the integration, aspects such as chip layout, wire bonding design rules, capability limitation, passive integration, etc. need to be considered and may be challenging. For instance, it may be necessary for a package designer to take care about parasitic phenomena. Hence, package design may not always be straightforward.

For instance when designing a high voltage gallium nitride half-bridge package with logic integration, it may be a challenge to integrate the corresponding electronic constituents.

Generally, the design of chip packages shall lead to low losses and a compact design.

According to an exemplary embodiment, a semiconductor package can be provided with a carrier having an electrically conductive routing or wiring structure at a top main surface. One or more electronic components embodied as lateral semiconductor chip may be arranged in flip-chip configuration on the carrier, i.e. with its active region facing the carrier. Advantageously, the routing structure may then be used for electrically connecting the chip-type surface mounted electronic component(s). By establishing additional electrically conductive connections between, on the one hand, bond wires and, on the other hand the carrier and/or the electronic component(s), the flexibility of creating an electrically conductive coupling may be increased. In a plan view on the main surface of the carrier accommodating the at least one chip-type electronic component, the bond wires may cross or intersect with the routing structure, although the bond wires may be guided over or under the routing structure in a bridge-like configuration. This may allow to construct a package with short electrically conductive connection paths. The bond wires bridging the routing structure may also help to keep electric connection paths short and may thus be realized short as well. Beneficially, low electrical losses, high signal quality and low energy dissipation may become possible. This may have a positive impact on electrical and thermal reliability as well as on package performance. At the same time, space consumption of the package may be kept reasonably small, which may promote manufacturability with low effort.

In a preferred embodiment, the above-described package architecture may be applied to design a scalable integrated high voltage gallium nitride package.

Exemplary embodiments may benefit from a carrier routing flexibility. A routable carrier may for instance be provided with a thick metal structure (for instance made of copper) to achieve excellent thermal and electrical performance. Advantageously, the carrier may be embodied as a two-layer carrier, wherein a carrier embodied as an organic carrier may be preferably used. Using such a carrier, a tie-bar less package may be created. Advantageously, an easy passive integration may be achieved with the package configuration according to exemplary embodiments.

In an embodiment, a package may be provided in which a carrier pad may be connected to a chip pad by one or more bond wires using a wire bonding configuration. For example, such a package design may allow to provide one additional redistribution structure (in particular redistribution layer) with low effort. Such a design may allow to reduce or even minimize a number of bond wires and can enable a connection to cross over traces in a routable carrier.

According to another advantageous aspect, it may be possible to mix or combine the aforementioned measures with a flip-chip configuration of one or more chip-type electronic components. Such a flip-chip design may enable a short interconnect distance, which may reduce or even minimize parasitic phenomena. Moreover, a flip-chip design may enable to provide a top sided cooling (TSC) ready structure, in particular when all chips of the package are arranged in a flip-chip configuration. Furthermore, a flip-chip design may enable a clip like connection of the carrier.

Exemplary embodiments may provide a package with semiconductor chips arranged in a half bridge configuration. Such a half bridge package may be configured on the basis of high voltage gallium nitride power chips with logic integration.

In particular, three flip-chips (or two flip-chips and a third one with terminal(s) on the top side) may be mounted on a carrier, and a pad-to-pad wire bonding connection may be established. Wire bonds may be formed for creating a carrier-to-carrier connection. Furthermore, bond wires may be arranged to fly over routings. Advantageously, this may enable a beneficial integration while complying with wire bond design rules. Advantageously, the described package architecture may be less picky what concerns chip pads for wire selection. Beneficially, exemplary embodiments may reduce a wire bonding temperature on an organic carrier. This may be due to the fact that heat does not need to transfer to the die. Furthermore, it may be possible in exemplary embodiments to use routings to assist to complete establishing a desired connection. Bond wires can cross-over the routing structure on a top side. Advantageously, exemplary embodiments may contribute to a shrinkage of the package due to the short electric connections. At the same time, thermal performance may be improved, since heat dissipation due to short electric connections and thus low ohmic losses may be reduced. In particular, it may be possible to shorten or reduce thermal paths in the package, in particular from a wafer front side directly to an exposed pad. Advantageously, it may also be possible to create metal-to-metal connections in the thermal path.

According to an exemplary embodiment, it may be possible to further enhance thermal performance of a package. In particular, a package ready for top sided cooling may be provided. The design according to exemplary embodiments may be particularly advantageous for a leadless package. Advantageously, a package according to an exemplary embodiment may have a hidden tie bar or no tie bar at all. Beneficially, a package may be provided with an increased interconnect area. Moreover, a passive integration may be possible as well. Package shrinkage according to exemplary embodiments may enhance performance and reduce manufacturing effort.

Exemplary embodiments may provide a package architecture supporting in particular integrated gallium nitride chip design. This may allow to provide a package with high energy efficiency. Thus, reduction of carbon dioxide emission may be reduced as well.

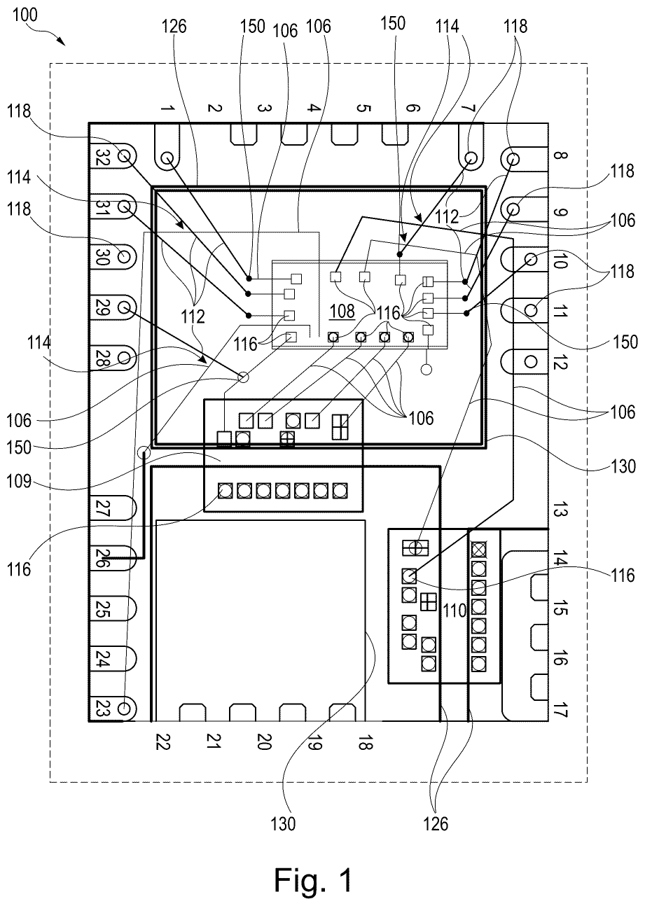

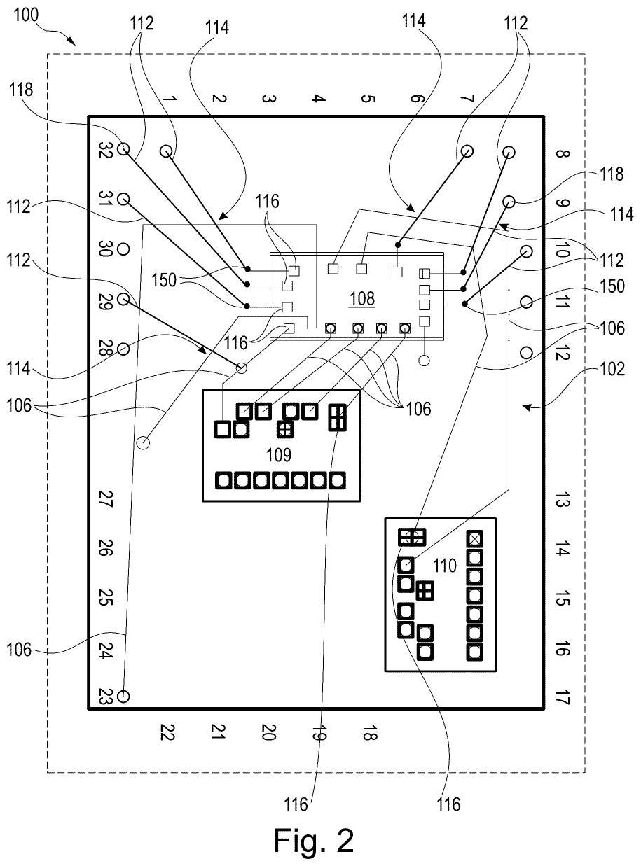

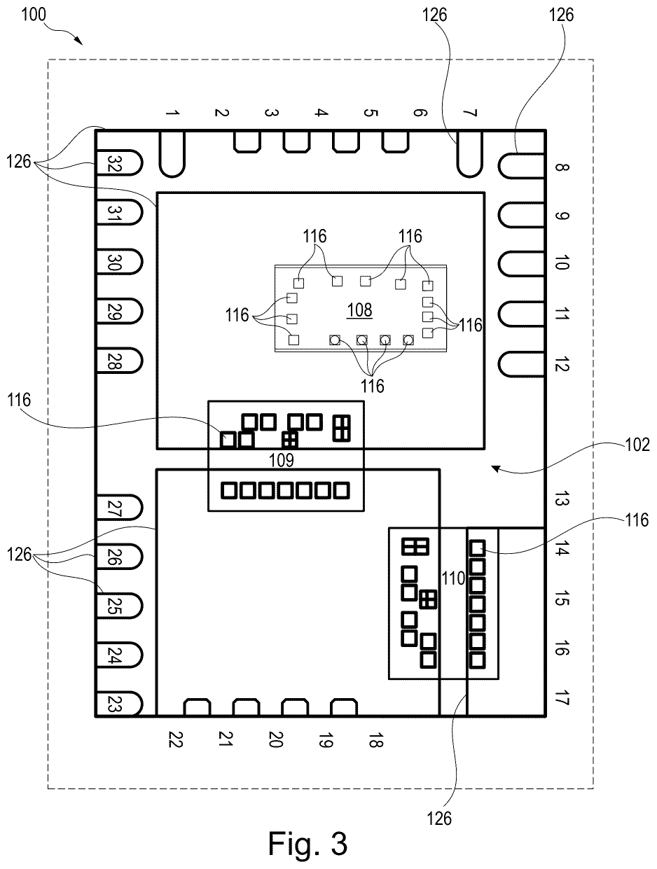

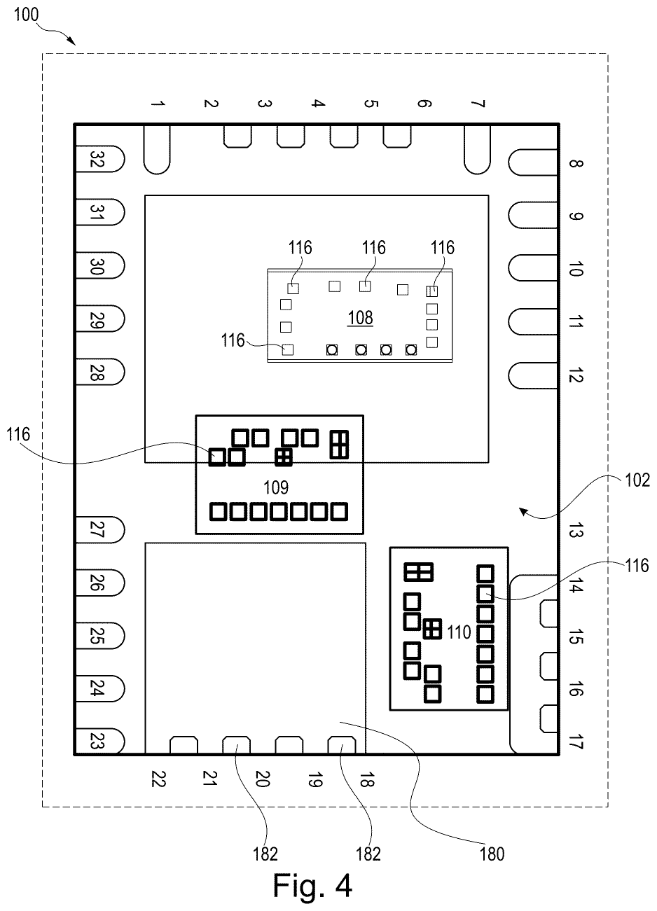

FIG. 1 shows a plan view of all layers from a top side of a package 100 according to an exemplary embodiment. FIG. 2 shows a plan view of a first layer of the package 100 according to FIG. 1. FIG. 3 shows a plan view of a second layer of the package 100 according to FIG. 1. FIG. 4 shows a plan view of a bottom layer of the package 100 according to FIG. 1. More precisely, FIG. 4 illustrates a surface of a second metal layer (or bottom layer metal), overlapping with chips view.

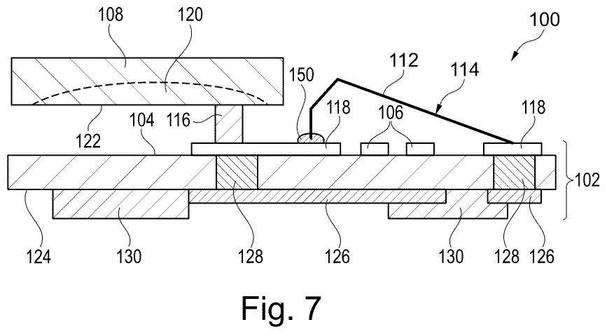

Before details will be described, the general package arrangement of FIG. 1 to FIG. 4 will be summarized. Generally, a cross-section of the package 100 according to FIG. 1 to FIG. 4 may have a similar design is shown in FIG. 7. In FIG. 1, package constituents of all layers are illustrated, to give an overview. FIG. 2 shows a top sided metallic layer structure of the package 100 showing in particular surface mounted electronic components 108-110 and a horizontal routing structure 106. FIG. 3 shows a further metallic layer structure beneath the metallic layer structure according to FIG. 2. At a bottom-side of the package 100, an electrically insulating patterned solder mask 130 can be provided for defining a footprint in accordance with a mounting of package 100 on a mounting base (not shown), such as a printed circuit board.

More specifically, package 100 comprises a carrier 102, which may be an organic laminate with electrically conductive structures thereon and therein. For instance, carrier 102 may be a printed circuit board (PCB). Such an organic carrier 102 may comprise organic electrically insulating material, such as resin, prepreg, FR4, etc. For instance, said organic electrically insulating material may comprise a resin with reinforcing glass fibers therein. Electrically conductive structures of the carrier 102 may for instance be made of copper.

Referring to FIG. 2, the carrier 102 has an upper main surface (see reference sign 104 in FIG. 7) on which an exposed electrically conductive routing structure 106 is formed. Said routing structure 106 may be a horizontal wiring, which may be a planar horizontal patterned metal layer, for instance made of copper. Furthermore, the carrier 102 has a lower main surface (see reference sign 124 in FIG. 7) opposing said upper main surface 104. An electrically conductive layer structure 126 may be formed on the lower main surface 124 of the carrier 102, see FIG. 3. A patterned electrically insulating solder mask 130 may be applied on part of the electrically conductive layer structure 126 for defining exposed and covered portions of said electrically conductive layer structure 126. It is also possible that part of the solder mask 130 is applied on electrically insulating material (for instance resin, prepreg or FR4) of the carrier 102.

In addition, electrically conductive vias (see reference sign 128 in FIG. 7) may be provided as vertical interconnect structures extending vertically between the two opposing main surfaces 104, 124 of the carrier 102. Such electrically conductive vias or other vertically interconnect structures (for instance metal posts or pillars) may extend vertically through the carrier 102 and may electrically connect the routing structure 106 with the electrically conductive layer structure 126. Advantageously, the carrier 102 is a two-layer carrier 102 with exactly two horizontally extending layer structures in form of the routing structure 106 arranged on the main surface 104 of the carrier 102 and the electrically conductive layer structure 126 exposed at the further main surface 124 of the carrier 102. In this context, the term two-layer carrier may denote the fact that carrier 102 has exactly two horizontal patterned metal layers. In other embodiments, carriers 102 with another number of horizontal patterned metal layers may be foreseen, although the embodiment of FIG. 1 to FIG. 4 has the advantage of simplicity. The two horizontal patterned metal layers of FIG. 1 to FIG. 4 may be formed on and/or embedded in the dielectric material of carrier 102 and may be interconnected electrically, as described, by one or more vertical through connections, such as metallized vias.

Moreover, a first electronic component 108 is surface mounted on the first main surface 104 of the carrier 102, more specifically on the routing structure 106. Consequently, chip pads 116 of the electronic component 108 may be electrically coupled with traces of the routing structure 106. The first electronic component 108 is configured as a lateral semiconductor chip and is mounted in a flip-chip configuration on the carrier 102. Consequently, chip pads 116 of the first electronic component 108 may face the carrier 102 and may be directly connected to elements of the routing structure 106. By taking this measure, it may be possible to directly electrically couple said chip pads 116 of the first electronic component 108 with the routing structure 106, for instance by soldering. As already mentioned, the first electronic component 108 may be a lateral chip experiencing a substantially horizontal (rather than vertical) flow of charge carriers during operation. An active region (see reference sign 120 in FIG. 7) of the first electronic component 108, in which its monolithically integrated circuit element(s) may be integrated, may be arranged to face the carrier 102 rather than facing away from carrier 102. This may be denoted as a flip-chip configuration of the first electronic component 108. For example, the first electronic component 108 may be a transistor chip, more specifically a field-effect transistor chip. Thus, the monolithically integrated circuit element of the first electronic component 108 may be a field-effect transistor, such as a MOSFET (metal oxide semiconductor field effect transistor). Advantageously, the first electronic component 108 may be a semiconductor power chip. Preferably, the first electronic component 108 is manufactured as a gallium nitride chip.

Furthermore, a second electronic component 109 is surface mounted on the first main surface 104 of the carrier 102, more specifically on the routing structure 106. Consequently, chip pads 116 of the second electronic component 109 may be electrically coupled with traces of the routing structure 106. The second electronic component 109 is configured as a lateral semiconductor chip and is mounted in a flip-chip configuration on the carrier 102. Consequently, chip pads 116 of the second electronic component 109 may face the carrier 102 and may be directly connected to elements of the routing structure 106. By taking this measure, it may be possible to directly electrically couple said chip pads 116 of the second electronic component 109 with the routing structure 106. As already mentioned, the second electronic component 109 may be a lateral chip experiencing a substantially horizontal (rather than vertical) flow of charge carriers during operation. An active region of the second electronic component 109, in which its monolithically integrated circuit element(s) may be integrated, may be arranged to face the carrier 102 rather than facing away from carrier 102. This may be denoted as a flip-chip configuration of the second electronic component 109. For example, the second electronic component 109 may be a transistor chip, more specifically a field-effect transistor chip. Thus, the monolithically integrated circuit element of the second electronic component 109 may be a field-effect transistor, such as a MOSFET. Advantageously, the second electronic component 109 may be a semiconductor power chip. Preferably, the second electronic component 109 is manufactured as a gallium nitride chip.

In addition, a third electronic component 110 is surface mounted on the first main surface 104 of the carrier 102, more specifically on the routing structure 106. Consequently, chip pads 116 of the third electronic component 110 may be electrically coupled with traces of the routing structure 106. The third electronic component 110 is configured as a lateral semiconductor chip and is mounted in a flip-chip configuration on the carrier 102. Consequently, chip pads 116 of the third electronic component 110 may face the carrier 102 and may be directly connected to elements of the routing structure 106. By taking this measure, it may be possible to directly electrically couple said chip pads 116 of the third electronic component 110 with the routing structure 106. As already mentioned, the third electronic component 110 may be a lateral chip experiencing a substantially horizontal (rather than vertical) flow of charge carriers during operation. An active region of the third electronic component 110, in which its monolithically integrated circuit element(s) may be integrated, may be arranged to face the carrier 102 rather than facing away from carrier 102. This may be denoted as a flip-chip configuration of the third electronic component 110. For example, the third electronic component 110 may be a logic chip or a control chip controlling the first electronic component 108 and the second electronic component 109.

Although not shown in the embodiment of FIG. 1 to FIG. 4, it may be possible to provide a fourth electronic component which may be configured correspondingly as described above for the third electronic component 110. In such an embodiment, the control function for controlling the first electronic component 108 and the second electronic component 109 may be carried out by the third electronic component 110 and the fourth electronic component. In the embodiment of FIG. 1 to FIG. 4, however, the control of the first electronic component 108 and of the second electronic component 109 may be carried out by the third electronic component 110 alone.

Advantageously, the first electronic component 108, the second electronic component 109 and the third electronic component 110 may be interconnected for providing a half bridge function. In this configuration, one of the first electronic component 108 and the second electronic component 109 may be a high-side (HS) switch, whereas the other one may be a low-side (LS) switch. However, other electronic applications may be possible according to another embodiment.

Advantageously, the routing structure 106 directly connects the first electronic component 108, the second electronic component 109, and the third electronic component 110 with each other. Thus, the routing structure 106 electrically couples the first electronic component 108 with the second electronic component 109 and with the third electronic component 110 and establishes very short electric paths.

As best seen in FIG. 1 to FIG. 2, a plurality of oblong and curved (see FIG. 7) electrically conductive bond wires 112 electrically connect the routing structure 106 of the carrier 102 and one, two or all of the first electronic component 108, the second electronic component 109 and the third electronic component 110. In the plan view on the carrier 102 shown in FIG. 1 or FIG. 2, the bond wires 112 cross or intersect the routing structure 106 in crossing regions 114. However, in a side view (see for instance FIG. 7 for comparison purposes), it can be seen that the bond wires 112 may extend above the routing structure 106, for instance may extend out of the paper plane of FIG. 1. Consequently, such flyovers bond wires 112 may vertically bridge traces of the routing structure 106 in the respective crossing regions 114. The described design leads to very short electrically conductive connection paths, and consequently to high signal integrity and low losses. As a result, a compact package 100 may be obtained which has a high thermal reliability and electric performance.

More specifically, some or all of the bond wires 112 may be connected directly to the routing structure 106. In particular, a respective bond wire 112 may be directly connected to a respective electrically conductive trace of the routing structure 106 by a respective bond pad 150 (for the connection between two carrier pads 118, 118 via a bond wire 112, such a bond pad 150 is also shown in FIG. 7). For instance, each respective bond wire 112 may be coupled to an end section and/or to a middle section of the routing structure 106, in particular by a respective bond pad 150 or with direct physical contact. It may also be possible that for one, some or all bond wires 112 of the package 100, one section of the respective bond wire 112 is directly connected with one section of the routing structure 106, and another section of the routing structure 106 is connected to a chip pad 116 of the respective electronic component 108-110. According to another configuration, for one, some or all bond wires 112 of the package 100, one section of the respective bond wire 112 is directly connected with one section of the routing structure 106, and another section of the bond wire 112 is connected to a vertical electrical interconnector (see reference sign 128 in FIG. 7). The latter may be for example a metallized via of the carrier 102. As also shown in FIG. 1, at least some of the bond wires 112 may electrically couple the routing structure 106 with a respective carrier pad 118 of the carrier 102, for instance in an edge region of the carrier 102. In yet a further aspect, only a part of chip pads 116 of the respective electronic component 108-110 is connected to the routing structure 106, see the second electronic component 109 and the third electronic component 110.

In FIG. 4, reference sign 180 shows a big pad, and reference signs 182 show a cut off portion.

Concluding, the embodiment of FIG. 1 to FIG. 4 illustrates a package 100 which shows, in FIG. 1, all layers and all chip-type electronic components 108-110 with flip-chip configuration. Referring to FIG. 2, a first metallic layer and vias of carrier 102 are shown. Carrier routings, and wire bond flying over routings and connecting within carrier 102 are shown as well. By establishing a flip-chip configuration, the respective chip front side can have a bigger opening for providing a bigger interconnect area. A small amount or even no solder mask needs to be applied here. Referring to FIG. 3, a second copper layer of carrier 102 is illustrated. Such a second metal layer area may be configured to be large for thermal reasons, and may function for instance as built-in heat sink. Furthermore, a bottom-sided patterned solder mask 130 may be provided. The solder mask 130 partially covers and partially exposes the electrically conductive layer structure 126 on the bottom side of the carrier 102. For instance, this may be made for defining solderable and non-solderable portions on the bottom side of the package 100. Hence, the solder mask 130 may be configured to define a final footprint of the package 100 while respecting creepage distances. Advantageously, no tie-bar is needed for package 100 according to FIG. 1 to FIG. 4.

In view of the described manufacturing architecture of the package 100, it may have a very compact size. For instance, package 100 according to FIG. 1 to FIG. 4 may have a 6 mm×8 mm design. Furthermore, the described package architecture may lead to a package 100 with low warpage. Furthermore, simple and short bond wires 112 may ensure the desired electric interconnection together with the routing structure 106 and bond pads 150. Moreover, the described manufacturing architecture may be compatible with small chip pads 116.

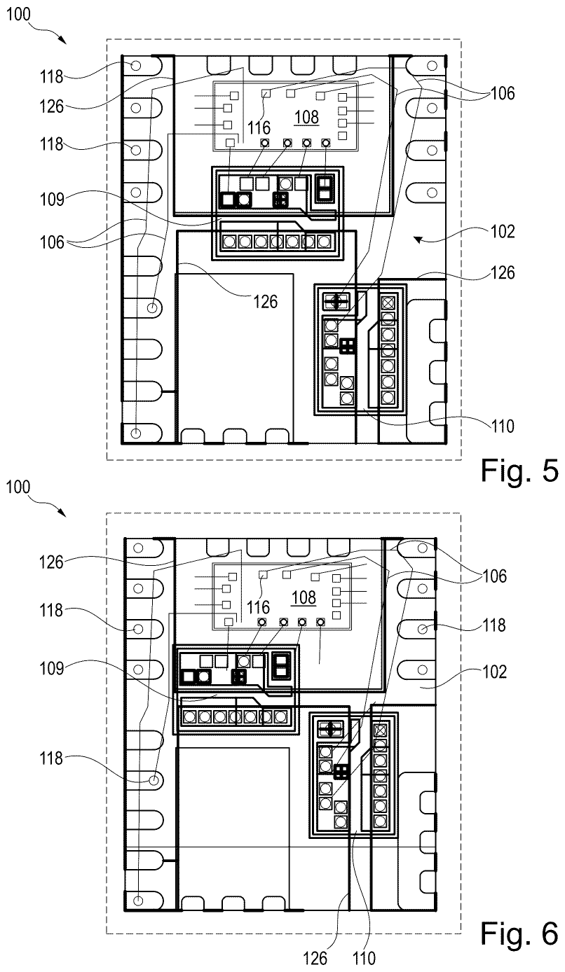

FIG. 5 shows a plan view of a package 100 according to another exemplary embodiment.

The embodiment of FIG. 5 differs from the embodiment of FIG. 1 to FIG. 4 in particular in that, according to FIG. 5, the space consumption of the package 100 is further reduced. For instance, FIG. 5 shows a 6 mm×5 mm package design. In particular, this may be accomplished by adjusting the chip locations. Descriptively speaking, moving the electronic components 108-110 closer together allows to further shrink package 100. This is due to the fact that in view of the simple wiring of the embodiment of FIG. 1 to FIG. 4 thanks to the combination of the routing structure 106 with the correspondingly connected bond wires 112, empty regions may remain which may be used for arranging electronic components 108-110 even closer together.

FIG. 6 shows a plan view of a package 100 according to yet another exemplary embodiment.

The embodiment of FIG. 6 differs from the embodiment of FIG. 1 to FIG. 4 in particular in that, according to FIG. 6, the space consumption of the package 100 is further reduced, even in comparison with FIG. 5. For instance, FIG. 6 shows a 5 mm×5 mm package design.

FIG. 7 shows a cross-sectional view of a package 100 according to another exemplary embodiment.

FIG. 7 shows a single electronic component 108 mounted on the carrier 102. However, one or more further electronic components (109, 110, etc.) may be surface mounted on the carrier 102 as well. FIG. 7 also shows that electronic component 108 is arranged face-down, i.e. with its active region 120 facing carrier 102. Hence, electronic component 108 is arranged in a flip-chip configuration also in FIG. 7.

FIG. 7 shows two carrier pads 118 on the first main surface 104 of carrier 102. A chip pad 116 of electronic component 108 is connected with one of said carrier pads 118. Furthermore, this carrier pad 118 is coupled by a bond pad 150 and a bond wire 112 to the other carrier pad 118. Each carrier pad 118 is connected through a respective vertically extending metallic via 128 to a respective section of the electrically conductive layer structure 126 on the bottom main surface 124 of the organic laminate-type carrier 102. Electrically conductive layer structure 126 is embodied as a patterned metal layer, for instance a patterned copper foil. An electrically insulating solder mask 130 partially covers the electrically conductive layer structure 126, and partially exposes the latter. Traces or wiring structures of routing structure 106 may extend for instance out of the paper plane of FIG. 7. In a plan view (not shown in FIG. 7) on the upper main surface 104 of the carrier 102, the aforementioned traces or wiring structures of routing structure 106 may cross or intersect bond wire 112 in crossing region 114. However, in the illustrated side view of FIG. 7, it can be seen that bond wire 112 bridges said traces or wiring structures of routing structure 106 by being arranged as a flyover structure extending above (and/or below, not shown) the routing structure 106.

The described and illustrated connection architecture leads to very short electric connection paths in package 100. This may lead to low electric losses, excellent signal quality and a relaxed heat management.

Advantageously, package 100 of FIG. 7 has a wire looping position, i.e. an uppermost position of bond wire 112, vertically lower than the die-type electronic component 108. Advantageously, this enables top side cooling of package 100.

From top to bottom, carrier 102 of package 100 has a first metallic layer (for instance made of copper) in form of routing structure 106, an intermediate via structure with metallic vias 128, and a second metallic layer (for instance made of copper) in form of electrically conductive layer structure 126. The electrically insulating portion of carrier 102 may comprise or consist of polymer materials.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claimed are intended to include within their scope such processes, machines, manufacture, compositions of matter, means, methods, or steps.

What is claimed is:

1. A package, comprising:
a carrier having a main surface on and/or in which an electrically conductive routing structure is formed;
a first electronic component being a lateral semiconductor chip and being mounted in a flip-chip configuration on the carrier to be electrically coupled with the routing structure; and
a plurality of electrically conductive bond wires electrically connecting the carrier and/or the first electronic component;
wherein the bond wires, in a plan view on the carrier, cross the routing structure in at least one crossing region and extend above or below the routing structure for bridging the routing structure in the at least one crossing region,
wherein in the at least one crossing region, the bridged routing structure electrically couples the first electronic component with a second electronic component.

2. The package of claim 1, wherein at least part of the bond wires are connected directly to the routing structure.

3. The package of claim 1, wherein for one, some or all of the bond wires, one section of the respective bond wire is directly connected with one section of the routing structure and another section of the routing structure is connected to a pad of the first electronic component.

4. The package of claim 1, wherein for one, some or all of the bond wires, one section of the respective bond wire is directly connected with one section of the routing structure and another section of the bond wire is connected to a vertical electrical interconnector of the carrier.

5. The package of claim 1, wherein at least part of the bond wires electrically couple a respective trace of the routing structure with at least one carrier pad of the carrier.

6. The package of claim 1, wherein the first electronic component has a plurality of chip pads only part of which are connected to the routing structure.

7. The package of claim 1, further comprising the second electronic component, wherein the second electronic component is a lateral semiconductor chip and is mounted in a flip-chip configuration on the carrier to be electrically coupled with the routing structure.

8. The package of claim 7, further comprising a third electronic component being a lateral semiconductor chip and being mounted in a flip-chip configuration on the carrier to be electrically coupled with the routing structure.

9. The package of claim 8, wherein the routing structure directly connects the first electronic component and the third electronic component.

10. The package of claim 8, wherein the first electronic component, the second electronic component and the third electronic component are interconnected to form a half bridge.

11. The package of claim 8, wherein the first electronic component is a power chip, the second electronic component is a power chip, and the third electronic component is a logic chip.

12. The package of claim 1, wherein the first electronic component is a transistor chip, a power chip, a logic chip, a driver chip and/or a gallium nitride chip.

13. The package of claim 1, wherein the carrier has a further main surface opposing the main surface, and wherein an electrically conductive layer structure is formed on and/or in the further main surface of the carrier.

14. The package of claim 13, further comprising a plurality of electrically conductive vias extending vertically through the carrier and connecting the routing structure with the electrically conductive layer structure.

15. The package of claim 13, wherein the carrier is a two-layer carrier with the routing structure arranged on the main surface of the carrier and the electrically conductive layer structure exposed at the further main surface of the carrier.

16. The package of claim 1, wherein the carrier is an organic substrate, a laminate substrate, a molded interconnect substrate, a pre-molded frame, or a leadframe.

17. The package of claim 1, wherein the routing structure electrically couples the first electronic component with a third electronic component.

18. A method of manufacturing a package, the method comprising:
providing a carrier having a main surface on and/or in which an electrically conductive routing structure is formed;
mounting a first electronic component being a lateral semiconductor chip in a flip-chip configuration on the carrier to be electrically coupled with the routing structure;
electrically connecting the carrier and/or the first electronic component by a plurality of electrically conductive bond wires; and
arranging the bond wires, in a plan view on the carrier, to cross the routing structure in at least one crossing region and to extend above or below the routing structure for bridging the routing structure in the at least one crossing region,
wherein the bridged routing structure in the at least one crossing region electrically couples the first electronic component with a second electronic component.
